(19) United States
(12) Patent Application Publication
(10) Pub. No.: US 2003/0191995 A1
(43) Pub. Date: Oct. 9, 2003

(54) System for communicating with synchronous device

(76) Inventors: Igor Anatolievich Abrosimov, St. Petersburg (RU); Alexander Roger Deas, Edinburgh (GB)

Correspondence Address: Maria Nilova, Office 501, 58, Moika Embankment, St. Petesburg, 190000, RU

(21) Appl. No.: 10/425,629

(22) Filed: Apr. 30, 2003

Related U.S. Application Data
(63) Continuation-in-part of application No. PCT/RU01/00486, filed on Nov. 5, 2001.

(30) Foreign Application Priority Data
Nov. 3, 2000 (GB) 0026849.0

(51) Int. Cl. G01R 31/28; G11C 29/00

(52) U.S. Cl. 714/719

(57) ABSTRACT

The present invention relates to systems for communicating with synchronous devices, in particular, to automatic test equipment (ATE) for memory device testing and, more specifically, to a test system for testing a high-speed synchronous memory device using DQS signals obtained from the memory device to achieve the precise fault strobe timing characteristics. The test system for testing a memory device comprises a synchronisation unit for triggering fault strobe generators with respect to DQS signals from the memory device under test. The invention is particularly appropriate for testing memory devices having reference signal for data receiver synchronisation, such as DDR Synchronous Dynamic Random Access Memory (DDR SDRAM), DDR SGRAM (Synchronous Graphics Random Access Memory), DDR II SDRAM, QDR SRAM, etc.

### CROSS-REFERENCE TO RELATED APPLICATIONS

This application is a continuation-in-part application of PCT/RU01/00486 filed on Nov. 5, 2001, claiming priority from GB application 0026849.0 filed on Nov. 3, 2000, all of which are incorporated herein by reference.

### FIELD OF THE INVENTION

The present invention relates to systems for communicating with synchronous devices, in particular, to automatic test equipment (ATE) for memory device testing and, more specifically, to a test system for testing a high-speed synchronous memory device, and a method of testing thereof.

### BACKGROUND OF THE INVENTION

Test systems used for testing memory devices should be able to test new memory devices at their maximum speeds. A test system generates test patterns, feeds them to the memory device under test and compares the data read from the memory device under test with what is expected, but the timing of the strobe and its relation to the address, data and control signals is a critical parameter: that is, it is subject to a very tight timing tolerance in high speed systems.

The invention is particularly appropriate for testing high-speed memory devices having a generating means for generating a data strobe signal, such as DDR Synchronous Dynamic Random Access Memory (DDR SDRAM), DDR SGRAM (Synchronous Graphics Random Access Memory), DDR II SDRAM, QDR SRAM, etc.

Synchronous dynamic random access memory, or SDRAM, was created in the 1990s to allow faster data access than EDO DRAM, which was the standard at the time. SDR (single data rate) SDRAM uses a synchronous interface with all inputs referenced to the rising edge of the clock, allowing all of the address, control and data input buffers to be identical. With careful design, this approach means that set-up times can be very small.

The initial operating speeds were set at 66 MHz, and so data could be output (or input) every 15 ns. This was developed in stages up to 166 MHz, but now SDR SDRAMs have reached their theoretical performance limits—heralding the entry of double data rate technology. DDR SDRAM data is driven relative to both edges of the clock, thus in effect doubling the data speed of memory. The main production speed this year is expected to be PC266 (using a clock frequency of 133 MHz), with the input and output data changing every 3.75 ns.

But the ever increasing speeds of memory devices and modules has made testing much more difficult. It is not only the increased data speeds that cause problems, but skew and jitter between I/O signals on the same device (or between devices on a module) become significant. The output data valid window of a device is dramatically reduced, and placement of the fault strobe becomes critical.

A computer system accesses the memory by writing data to particular locations and then reading those locations. The read timing includes the assertion of an address and control signals. Commonly the address is supplied on a multiplexed bus as an X and Y address latched by particular commands, such as Active, Read/Write and Clock in an SDRAM application.

When testing a memory device, data are captured either at or around the edge of data strobe signal. If a memory device does not provide correct reading of data at the time of the data strobe, then a memory fault will occur in the system the memory device is used.

Typically, ATE systems synchronise their receivers with the main clock signal There is a known technique in electronic device testing where a particular logical event (such as a predetermined number of clock cycles) provides a trigger signal U.S. Pat. No. 3,843,893, for example, describes a test system generating a trigger signal to synchronise an external test instrument, e.g. oscilloscope, to a circuit under test. This known system comprises a comparison means for comparing a digital signal with the expected bit pattern and generating a trigger signal.

This technique, when applied to high speed modern memory devices such as DDR SDRAM receivers, requires an extremely high accuracy of data reading. A tester offering such an accuracy would be rather expensive, while with traditional testers memory devices that are within a specification can be regarded as failed and discarded due to inaccuracy in fault data reading. Thus, a traditional tester will not provide maximum possible yield resulting in reduction of revenues obtained by memory fabs.

To be more specific, the above-mentioned data output valid windows for various types of memory devices will now be discussed in detail.

For SDR SDRAM, the data valid window illustrated in FIG. 1, is large enough. After a read command, the output data is made valid two or three clock cycles later (depending on the CAS latency being used). All of the output data becomes valid at tac (the data access time) after the rising edge of the clock signal (which is typically 5.4 ns for a 133 MHz device). The output data then remains valid until at least toh after the next rising edge of the clock (typically 2.7 ns).

If the period of the clock is T, the minimum data valid window for an SDRAM device (or module) is given by (T−tac)+toh. Inserting typical values for a PC133 device gives a minimum data valid window of (7.5−5.4)+2.7=4.8 ns. This is a large enough window in which to place a fault strobe, even with low cost test equipment that has a fault strobe edge placement accuracy of more than 1 ns.

With DDR SDRAM, the operation of a read cycle has some significant differences The clock is a double-ended input signal, output data is driven relative to both edges of the clock, and an additional bidirectional data strobe signal (DQS) is used. FIG. 2 shows the data valid window of an 8-bit device, constructed from the AC characteristics of a typical PC266 memory device. For a read operation, the DQS signal toggles at exactly the same time as transition of the output (read) data occurs from one access to the next. This transition should ideally occur in the centre of the spread of transitions of the DQ or data signals.

A special note can be made with respect to the meaning of the term “DQ”. “D” is often used by specialists to denote an input through which a memory device would accept data for storage, and “Q” means an output through which data read from the memory would be presented. In one popular variation the memory is split into 4, 8, 16 or more equal segments, and these segments are accessed in parallel Such a configuration multiplies the “D” and “Q” pins required for transferring data into and out of the IC. In order to keep the package small, the input and output functions are commonly combined to share the same pin which is now called a “DQ” pin. Correspondingly, a signal transmitted through this pin is referred to as a “DQ” signal.

The key timing parameters are denoted by tdqsq (DQS to DQ skew, which is typically 0.5 ns for a PC266 device) and tqh (DQS to DQS hold, which is typically (thp−0.75 ns) for a PC266 device, where thp is the minimum clock low/high time). The data valid window for one device is given by (tqh−tdqsq). Using typical values for a PC266 device (where the clock cycle, T, is 7.5 ns) gives a data valid window of (0.45T−0.75)−0.5, or 2.125 ns. The data valid window for testing one DDR SDRAM is relatively small compared to single data rate memories (2.125 ns versus 4.5 ns). But it gets even smaller if there is more than one DDR memory device on a module, where jitter and skew between devices can become significant. FIG. 3 shows the effects of having two devices (X and Y) in a module, each with a DVW of 2.125 ns. If these signals are offset from each other by the skew of the DQS signals from the individual memory devices (DQSx and DQSy), the transitions of the DQS signal of each device on a module fall in a window defined by the parameter tdqsck. This determines the limits of the DQS jitter that for PC266 device, has a maximum and minimum value of (tdqsck of ±0.75 ns) with respect to the clock.

If DQSx and DQSy are skewed by the maximum and minimum values of tdqsck, then the DVW for the module is equal to [DVW for a device−2(tdqsck)], or 0.625 ns.

When performing a read operation on the module, placement of the fault strobe within the DVW is critical. The ideal memory test equipment would have an accuracy in the order of ±300 ps to reliably position the fault strobe in the DVW, triggered by the respective DQS signal of the device.

Further complication is added by the skew and jitter effects of the clock signals on the module, as well as the varying track lengths associated with some signals (which can cause an impedance mismatch). These can reduce the DVW by a further ±0.5 ns, leaving it at almost 0—if not a negative value.

Thus, the problem of maintaining high accuracy of testing high speed memory devices, on the one hand, and the requirement to obtain reliable test results around the actual data strobe of a memory device, on the other hand, creates the necessity of developing a method for accurate fault strobe timing so as to achieve greater test reliability than that with the traditional methods.

### BRIEF SUMMARY OF THE INVENTION

The object of the present invention is the provision of a system for communicating with synchronous devices.

Another object of the present invention is the provision of devices, such as a test system, with highly precise fault strobe timing.

These objects are achieved by providing a test system using data strobe signals obtained from the memory device to achieve the precise fault strobe timing characteristics.

More specifically, these objects are achieved by providing a test system for testing a synchronous memory device having a data strobe generating means for generating at least one data strobe signal, the test system comprising a test pattern generator for generating a pattern of test signals; a transmitter for driving the test signals from the test pattern generator to the memory device; a receiver for receiving a response data signal from the memory device as a response to the test signals; a fault strobe generating and synchronizing means including a fault strobe generator for generating a fault strobe signal; and further including a response data signal delay means connected to the receiver; and a comparator for comparing the response data signal received from the memory device with the expected data, the comparison being triggered by the fault strobe signal; wherein the response data signal is fed to the delay means, while the data strobe signal is fed to the fault strobe generator, so that the fault strobe is generated by modifying the data strobe signal.

The fault strobe generator can be implemented as an adjustable delay means. In this case fault strobe is generated by delaying the data strobe signal.

As a rule, said pattern of test signals includes address, data, control and clock. signals.

The transmitter can be implemented in a self-calibrating transmitter, wherein for each register of the transmitter a corresponding feedback loop is associated for the relative alignment of register's channels timing in relation to the reference signal.

The adjustable delay means can be implemented in at least one vernier.

The number of the verniers usually corresponds to the number of the data strobe signals.

Further, these objects are achieved by providing a method of testing semiconductor devices, the method including: a step of transmitting a pattern of signals for accessing memory elements within the device, a step of receiving response signals at a predefined moment of fault strobe for detecting failures in the memory elements, and a step of processing test results, wherein the fault strobe is generated by modifying the data strobe signal.

The modification of the data strobe signal can be effected by delaying this signal in an adjustable manner.

The advantage of the present invention is the ability of an ATE system using a means for fault strobe timing synchronisation incorporated in the testing system to reduce or substantially eliminate the timing skew by triggering fault strobes using the DQS signals from the device under test, and thus to enhance the accuracy of testing and provide acceptable and adequate testing of high-speed synchronous memory devices, such as DDR SDRAM devices.

Another aspect of the present invention is a method of testing semiconductor devices including a step of transmitting a pattern of signals for accessing memory elements within the device, a step of receiving response signals at a predefined moment of fault strobe for detecting failures in the memory elements and a step of processing test results, wherein the fault strobe is generated by modifying the data strobe signal.

Preferably, the modification of the data strobe signal is effected by adjustably delaying this signal.

### BRIEF DESCRIPTION OF THE SEVERAL VIEWS OF THE DRAWING

For a better understanding of the present invention and the advantages thereof and to show how the same may be carried into effect, reference will now be made, by way of example, to the following description with reference to the accompanying drawings in which:

FIG. 1 is a diagram showing the data valid window and timing of a read cycle for SDR SDRAM;

FIG. 2 is a diagram showing the data valid window of an 8-bit DDR SDRAM;

FIG. 3 is a diagram showing the data valid window of a module with more than one DDR memory device;

FIG. 4 is a schematic block diagram of the memory test system with fault strobe synchronisation in accordance with the preferred embodiment of the present invention;

FIG. 5 is a schematic diagram of the synchronisation unit in accordance with the present invention; and

FIG. 6 is a timing diagram illustrating the strobe synchronisation in accordance with the present invention.

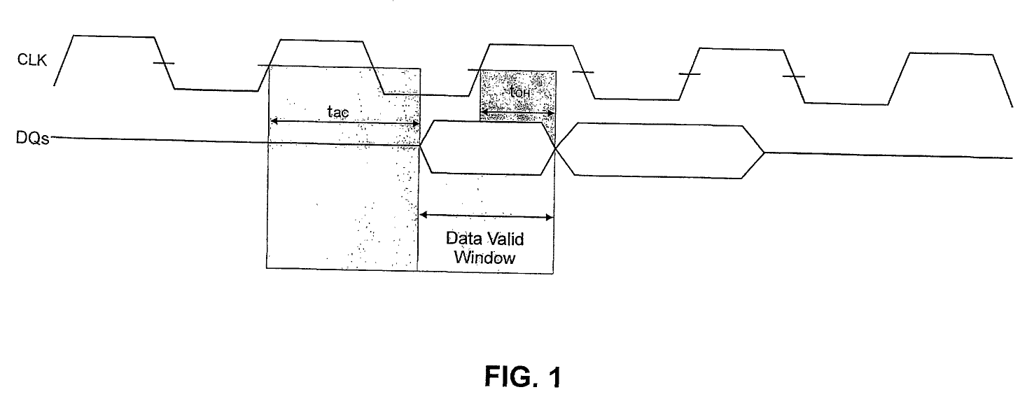

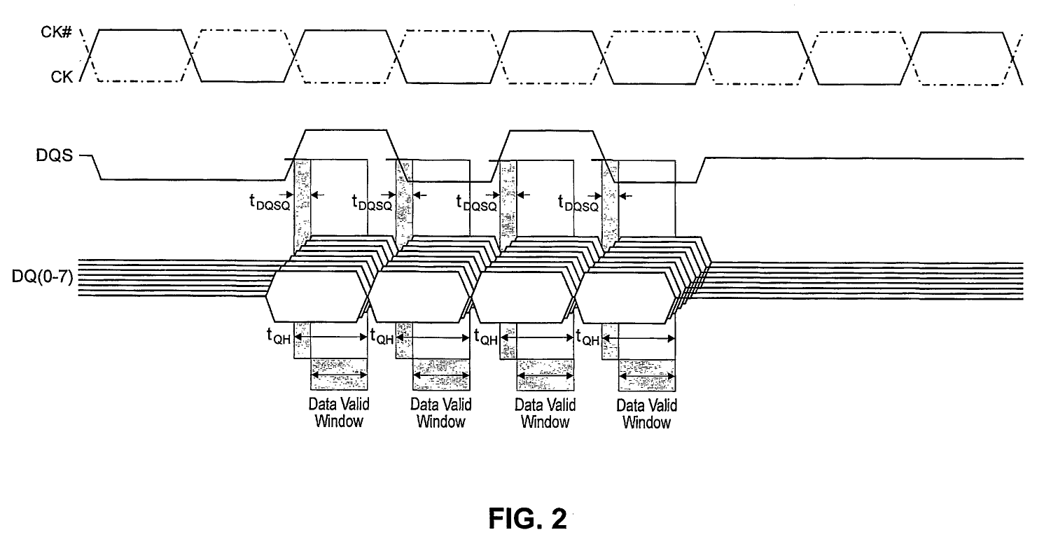

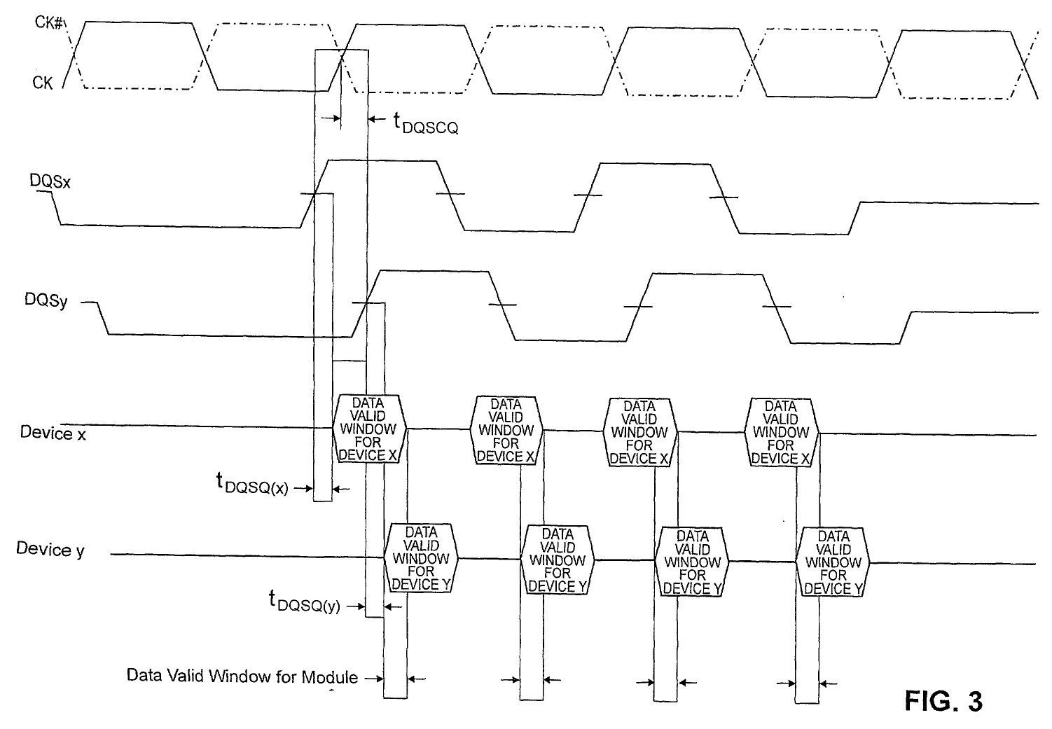

### DETAILED DESCRIPTION OF THE INVENTION

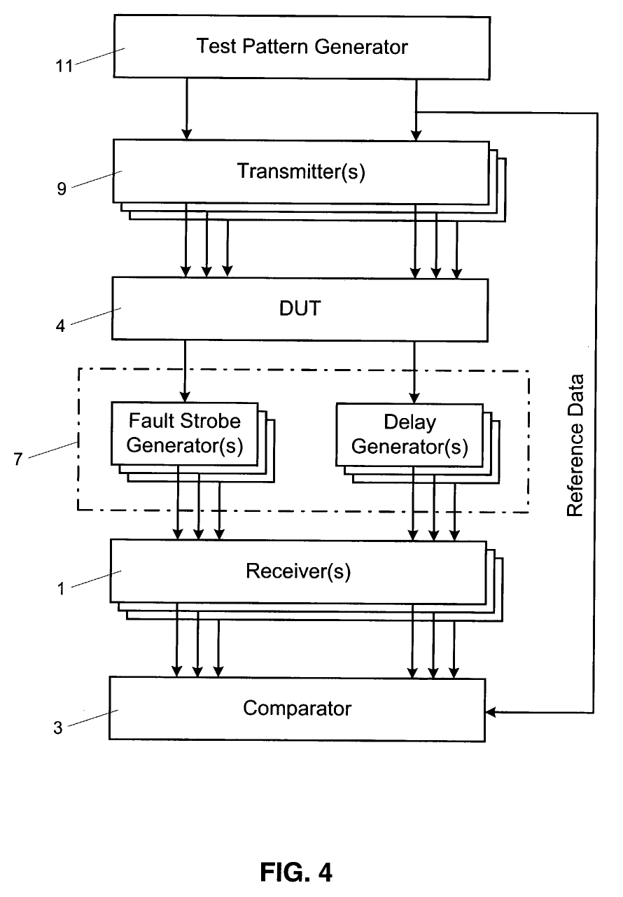

In FIG. 4, an example embodiment of the memory test system in accordance with the proposed invention is presented.

The system is intended for testing a synchronous memory device under test 4, e.g. a DDR SDRAM type. As mentioned earlier, this memory device is of a type that has a data strobe generating means for generating at least one data strobe signal or, in other words, DQS signal.

A test pattern generator 11 provides an appropriate sequence of test signals including address, data, control and clock signals. The test pattern generator can be provided, if necessary, with a suitable SDR (single data rate) to DDR (double data rate) converters.

Preferably, the test pattern generator is bT72 manufactured by Acuid Corporation Ltd.

As shown in the diagram of FIG. 4, data transmitters 9 connected to the test pattern generator are driving the test signals to the memory device 4 under test; and, in response to the test signals, a data signal which is a DQ signal, is received from the memory device 4 by receivers 1.

A preferable transmitter for use within the claimed memory test system is a self-calibrating transmitter as specified in PCT/RU00/00188 filed May 22, 2000 and U.S. Provisional application 60/228,115 filed Aug. 28, 2000, the whole disclosure of these applications (filed in the name of the present applicant) being incorporated herein by reference. A preferable receiver for use within the claimed memory test system is a SSTL16857 manufactured by Philips Inc.

The outputs of the receivers are connected to a fault comparator or fault logger 3 for comparing the response data signal received from the memory device with the expected data fed directly from the test pattern generator. The fault logger 3 can be implemented as a digital comparator.

Preferably, the signals are transmitted from the transmitters to the device 4 under test via a relay matrix (not shown in the drawings for simplicity) to permit switching on/off the device 4 from the test system.

A fault strobe generating and synchronizing means 7 is provided to match the fault strobe timing with the DQS signals received from the device 4 under test. The means 7 includes a fault strobe generator for generating a fault strobe signal; and a response data signal delay means connected to the receiver.

The fault strobe generator is implemented in a plurality of delay generators, e.g. verniers. According to the invention, respective DQS signals are fed to these verniers from the memory device. Thus, each fault strobe is generated by modifying the data strobe signal or DQS signal, more specifically, by delaying this signal in an adjustable manner. Preferably, the verniers are Edge 629 verniers, manufactured by Edge Semiconductors (US). The number of verniers corresponds to the number of DQS signals from the device under test.

The response data signal delay means is provided for delaying the DQ data from the memory device to provide the possibility of setting up a negative timing delay intervals for the fault strobe with respect to the received DQS signals. The delay means are implemented in delay elements that can be constant delays, e.g. segments of a transmission line of a predetermined delay value. The number of the delay elements corresponds to the number of data lines from the device under test. It shall be appreciated that the number of DQS signals is defined by the DUT. Each DQS corresponds to a particular field, or portion in the data. Thus, for example, in standard PC1600 DDR memory module with 72 DQs built from the chips having 4 DQs each, the amount of DQSs will be 18, wherein each DQS corresponds to each related 4 DQs field.

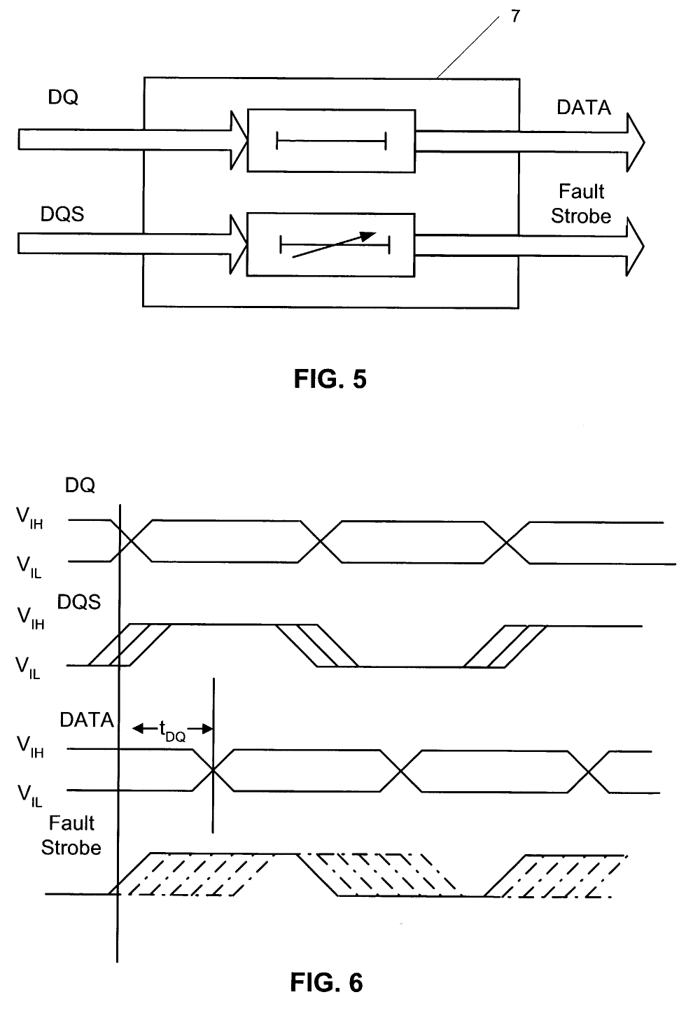

The system operates as follows. The test pattern generator 11 generates an appropriate sequence of test signals fed to the transmitters 9 and then transmitted to the device 4. The fault strobe generating and synchronizing means 7 receives the DQ and DQS signals from the DUT and outputs data and fault strobe signals to the receivers 1, as shown in FIG. 5 schematically illustrating the processing of one pair of the plurality of DQ and DQS signals in the fault strobe generating and synchronizing means 7. Shown in FIG. 6 are the timing diagrams of these signals applied to the input of the means 7 and of the fault strobe and data signals received at the output of these means.

The input DQ signal is delayed by means of the delay element. The time t_{dq} of delay is preferably close to a half of a range of the vernier in the DQS path.

The DQS signal is delayed by the verniers in an adjustable manner, so that the position of the resulting fault strobe can be set up in the interval covering both the end of the previous bit, and the beginning of the current bit. This allows to identify the actual positions of data transitions.

The fault strobe is thus synchronised with high accuracy. It shall be noted that the DQS signal have very strict parameters providing the accuracy of ±0.2 ps as compared to the system clock signal having the accuracy of ±0.5 ps.

The response signals are outputted into the receivers 1, and the data are fed to the fault logger 3 which compares real it with the expected reference data coming from the test pattern generator 1. The fault data from the fault logger 3 can further be downloaded to a central control unit of a controlling computer which preferably holds the accumulated data in an encoded format. The fault data can also be represented in a bitmap format for viewing the faults.

It will be appreciated that the above description and the figures are example embodiment only, and various modifications may be made to the embodiment described above within the scope of invention defined by the appended claims.

We claim:

1. A test system for testing a synchronous memory device having a data strobe generating means for generating at least one data strobe signal, the test system comprising:
a test pattern generator for generating a pattern of test signals;
a transmitter for driving the test signals from the test pattern generator to the memory device;
a receiver for receiving a response data signal from the memory device as a response to the test signals;
a fault strobe generating and synchronizing means including a fault strobe generator for generating a fault strobe signal; and further including a response data signal delay means connected to the receiver; and
a comparator for comparing the response data signal received from the memory device with the expected data, the comparison being triggered by the fault strobe signal;
wherein the response data signal is fed to the delay means, while the data strobe signal is fed to the fault strobe generator, so that the fault strobe is generated by modifying the data strobe signal.

2. The test system according to claim 1, wherein the fault strobe generator is implemented in an adjustable delay means.

3. The test system according to claim 1, wherein said pattern of test signals includes address, data, control and clock signals.

4. The test system according to claim 1, wherein the transmitter is a self-calibrating transmitter, wherein for each register of the transmitter a corresponding feedback loop is associated for the relative alignment of register's channels timing in relation to the reference signal.

5. The test system according to claim 2, wherein the adjustable delay means is implemented in at least one vernier.

6. The test system according to claim 5, wherein the number of the verniers corresponds to the number of the data strobe signals.

7. The test system according to claim 1, comprising a plurality of transmitters for driving the test signals from the test pattern generator to the memory device.

8. The test system according to claim 1, comprising a plurality of receivers for receiving a response data signal from the memory device.

9. The test system according to claim 1, comprising a plurality of delay elements.

10. A method of testing semiconductor devices including:
a step of transmitting a pattern of signals for accessing memory elements within the device;
a step of receiving response signals at a predefined moment of fault strobe for detecting failures in the memory elements; and
a step of processing test results,
wherein the fault strobe is generated by modifying the data strobe signal.

11. The method of testing of claim 10, wherein said modification of the data strobe signal is performed by delaying this signal in an adjustable manner.

12. A system for communicating with a synchronous device having a data strobe generating means for generating a data strobe signal, the system comprising:
a data pattern generator for generating a pattern of data signals;
a transmitter for driving the data signals from the data pattern generator to the synchronous device;
a receiver for receiving a response data signals from the synchronous device as a response to the data signals;
a reference strobe generator for generating a reference strobe signal;
a register for receiving the response data signals received from the synchronous device, the register being latched by the reference strobe signal; and
a delay means connected to the receiver;
wherein the response data signal is fed to the delay means, while the data strobe signal is fed to the reference strobe generator, so that the reference strobe is generated by modifying the data strobe signal.

13. The system according to claim 12, wherein the data strobe generator is implemented in an adjustable delay means.

14. The system according to claim 12, wherein said pattern of data signals includes address, data, control and clock signals.

15. The system according to claim 12, wherein the transmitter is a self-calibrating transmitter, wherein for each said register of the transmitter a corresponding feedback loop is associated for the relative alignment of register's channels timing in relation to the reference signal.

16. The system according to claim 13, wherein the adjustable delay means is implemented in at least one vernier.

17. The system according to claim 16, wherein the number of the verniers corresponds to the number of the data strobe signals.

18. The system according to claim 12, comprising a plurality of transmitters.

19. The system according to claim 12, comprising a plurality of receivers.

20. The system according to claim 12, comprising a plurality of delay elements.
